(19) United States
(12) Patent Application Publication
(10) Pub. No.: US 2006/0267197 A1
(43) Pub. Date: Nov. 30, 2006

(54) Integrated circuit device

(75) Inventors: Wen-Chin Chen, Hsin Chu Hsien (TW); Sheng-Shu Yang, Hsin Chu City (TW)

Correspondence Address: RABIN & Berdo, PC, 1101 14TH STREET, NW, SUITE 500, WASHINGTON, DC, 20005, US

(73) Assignee: TAIWAN TFT LCD ASSOCIATION

(21) Appl. No.: 11/494,503

(22) Filed: Jul. 28, 2006

Related U.S. Application Data
(63) Continuation-in-part of application No. 11/094,198, filed on Mar. 31, 2005.

(30) Foreign Application Priority Data
Dec. 14, 2004 (TW) 93138755

(51) Int. Cl. H01L 23/48

(52) U.S. Cl. 257/737; 257/E23.021

(57) ABSTRACT

A integrated circuit device made using LCD-COG (liquid crystal display-chip on glass) technique is disclosed. The integrated circuit device comprises a substrate, a plurality of dies having surfaces with a plurality of compliant bumps thereon. The compliant bumps are rearranged in any area of the dies for electrically connecting the dies and the substrate. The joint area of the bumps after rearrangement is smaller than the joint area of the bumps on the center. An adhesive is daubed on the joint area of the substrate and the dies for the purpose of jointing the substrate and the dies. By changing the position of the compliant bumps so that they are centrally corresponded on the dies without changing the electrical characteristics and the wiring arrangement of the dies, costs are lowered, reliability is increased and the glass substrate is less easily bent.

### CROSS-REFERENCE TO RELATED APPLICATIONS

This Application is a Continuation-in-Part of application Ser. No. 11/094,198, filed on 31 Mar. 2005, and entitled FLIP CHIP DEVICE.

### BACKGROUND OF THE INVENTION

1. Field of the invention

The present invention relates to an integrated circuit device, and more particularly to an integrated circuit device using a LCD-COG (liquid crystal display-chip on glass) technique.

2. Description of the Prior Art

In flip chip technology the jointed surface of the chip and the substrate form a pad or bump replacing the lead frame used in wire bonding technology. By directly stressing the bump or pad of the jointed surface of the chip and the substrate, electric conduction of the circuit is achieved. Recently, due to advances in the related technology, electronic products are becoming increasingly smaller and lightweight, so the applications of flip chip technology are increasing day by day.

The flip chip device of the prior art is the surface of the chip and the bumps formed by the substrate; the surface of the substrate is daubed with an adhesive and then the chip and the substrate are stressed to complete the flip chip device. Because the thermal expansion coefficient of the chip is different from that of the glass substrate, it may result in a certain degree of warp causing a disproportionate gap in the center and on the edge of the IC chip.

In order to improve upon the above stated disadvantages, U.S. Pat. No. 5,508,228 discloses “compliant electrically connective bumps for an adhesive flip chip integrated circuit device and methods for forming same”. As shown in FIG. 1, a compliant bump includes an IC chip 10, a compliant bump 14 covering a metal layer 16 thereon is formed on a bond pad 12 and connected to a glass base 18.

FIG. 2 shows U.S. Pat. No. 6,084,301 that discloses “Bump structure and method of manufacture”. A compliant bump includes an IC chip 20 with a plurality of conductive joints 22 and a protective film 26 covering the joints 22. A polymer bump 21 is formed on the joints 22 and a conductive metal layer 24 is formed on the polymer bump 21. Next, a metal layer 25 is formed on the conductive metal layer 24.

However, due to the limits of the initial arrangement of the IC, regardless of whether gold bumps or compliant bumps are used, these bumps will always have a ringed-type arrangement. FIG. 3 shows a plurality of bumps 31 ringed around an IC chip 30. This arrangement may however, have a negative effect when applied to the COG junction. As shown in FIG. 4, which is a schematic view of a warped COG of the flip chip device due to the thermal applied force of the prior art. The IC chip 34 and the substrate 35 are jointed via the bumps 36 and the conductive adhesive 37 (anisotropic conductive film). Because the thermal expansion coefficient of the IC chip 34 is different from that of the glass substrate 35, it causes a certain degree of warp creating a disproportionate gap in the center and on the edge of the IC chip thereby reducing the reliability of the products.

The inventor of the present invention recognizes the above shortage should be corrected and special effort has been paid to research this field. The present invention is presented with reasonable design and good effect to resolve the above problems.

### SUMMARY OF THE INVENTION

The prime object of the present invention is to provide an integrated circuit device that arranges the bumps in a central area of the die or on any area of the die. The joint area of the bumps after they have been rearranged is smaller than the joint area of the bumps in the center. The present invention reduces costs, increases their reliability and reduces bending.

For achieving the objects stated above, an integrated circuit device comprises a substrate, a plurality of dies having surfaces, and a plurality of compliant bumps thereon. The compliant bumps are rearranged on any area of the dies for electrically connecting the dies and the substrate. The joint area of the bumps after rearrangement is smaller than the joint area of the bumps on the center, and an adhesive is daubed on a joint area of the substrate and the dies for jointing the substrate and the dies. The compliant bumps are formed with a first metal layer, a bump and a second metal layer. By extending the first metal layer to change the position of the compliant bumps, the compliant bumps are disposed on the dies without changing the electrical characteristics or the wiring arrangement of the dies.

The integrated circuit device further comprises a plurality of non-connecting electrically compliant bumps disposed in a corner of the die or opposite to a side for maintaining the parallel of the joint.

It is to be understood that both the foregoing general description and the following detailed description are exemplary, and are intended to provide further explanation of the invention as claimed. Other advantages and features of the invention will be apparent from the following description, drawings and claims.

### BRIEF DESCRIPTION OF THE DRAWINGS

FIG. 1 is a schematic view showing the structure of the conductive compliant bump of the prior art;

FIG. 2 is another schematic view showing a conductive compliant bump structure of the prior art;

FIG. 3 is a schematic view showing the arrangement of the compliant bumps of the prior art;

FIG. 4 is a schematic view showing the warped COG of the integrated circuit device due to the thermal applied force of the prior art;

FIG. 5 is a schematic view showing the structure of the integrated circuit device of the present invention;

FIG. 6A is a top view showing the structures of the compliant bumps of the present invention;

FIG. 6B is schematic views showing the structures of the compliant bumps of the present invention;

FIG. 6C is an extended structure schematic view showing the first embodiment of the compliant bumps of the present invention;

FIG. 6D is an extended structure schematic view showing the second embodiment of the compliant bumps of the present invention;

FIG. 6E is an extended structure schematic view showing the second embodiment of the compliant bumps of the present invention;

FIG. 7 is a schematic view showing the second embodiment of the compliant bumps disposed on the chip of the present invention;

FIG. 8A is a schematic view showing the third embodiment of the compliant bumps disposed on the chip of the present invention;

FIG. 8B is a schematic view showing the fourth embodiment of the compliant bumps disposed on the chip of the present invention;

FIG. 9A is a schematic view showing the fifth embodiment of the compliant bumps disposed on the chip of the present invention;

FIG. 9B is a schematic view showing the sixth embodiment of the compliant bumps disposed on the chip of the present invention;

FIG. 10A is a schematic view showing the seventh embodiment of the compliant bumps disposed on the chip of the present invention;

FIG. 10B is a schematic view showing the eighth embodiment of the compliant bumps disposed on the chip of the present invention;

FIG. 11A is a schematic view showing the ninth embodiment of the compliant bumps disposed on the chip of the present invention;

FIG. 11B is a schematic view showing the tenth embodiment of the compliant bumps disposed on the chip of the present invention; and

FIG. 11C is a schematic view showing the eleventh embodiment of the compliant bumps disposed on the die of the present invention.

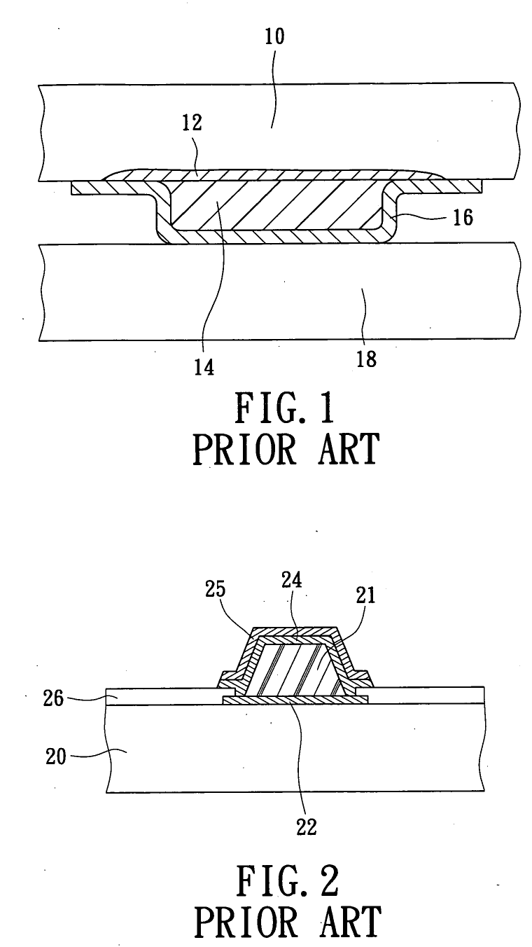

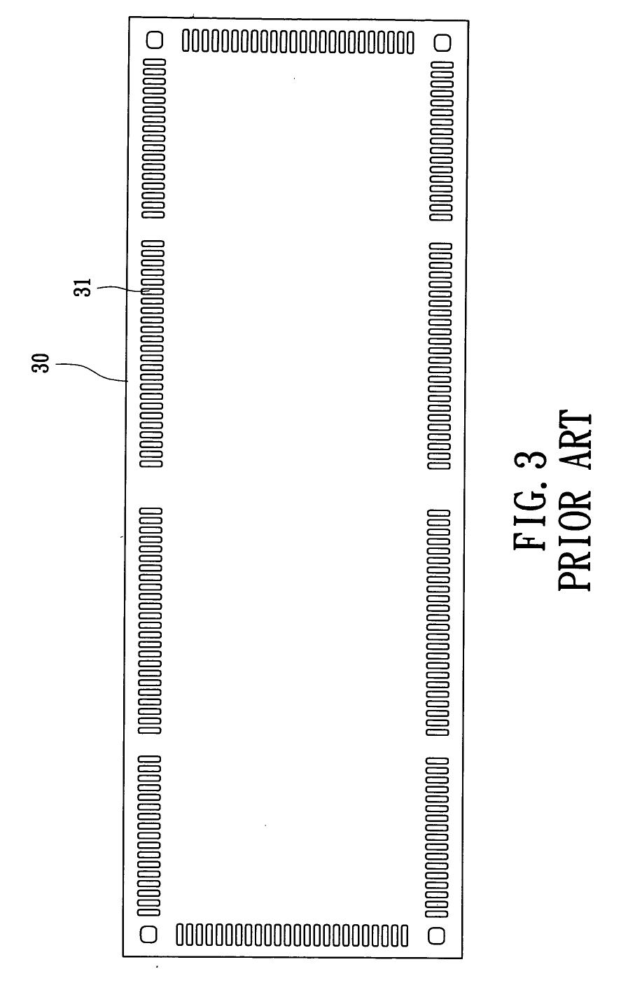

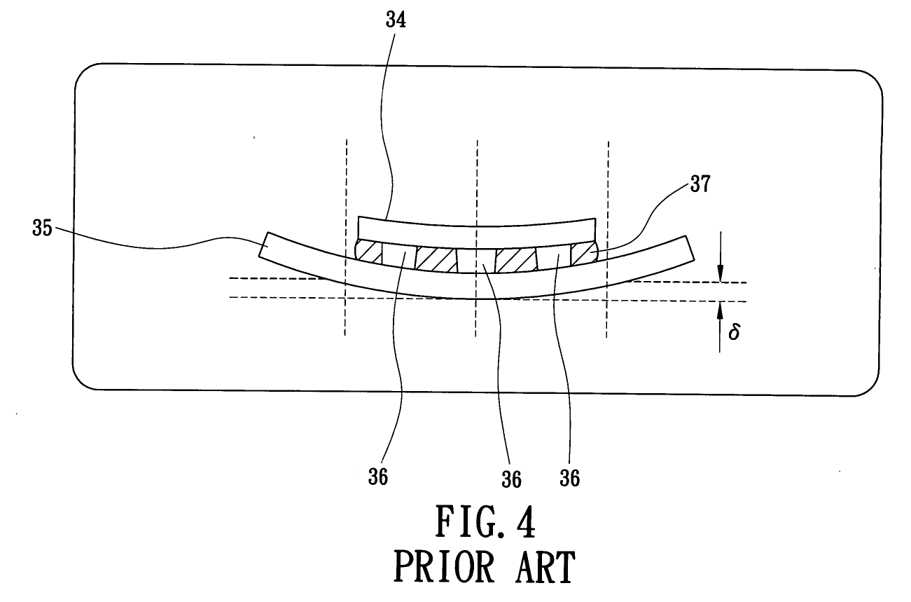

### DETAILED DESCRIPTION OF THE PREFERRED EMBODIMENTS

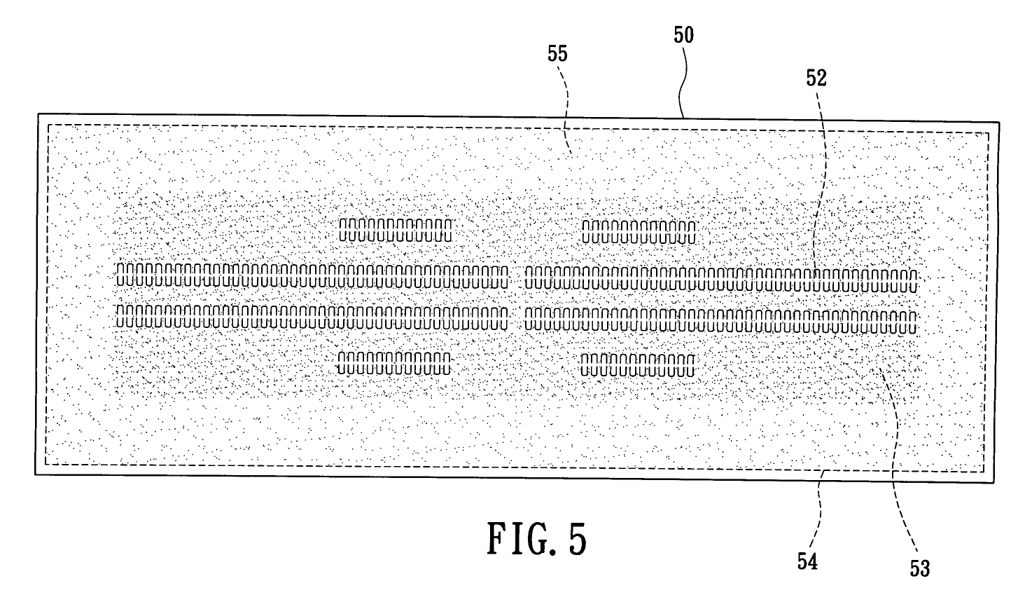

Reference is made to FIG. 5, which is 3a schematic view showing the structure of the integrated circuit device of the present invention. Included are a substrate 54, a die 50 which has a surface and a plurality of compliant bumps 52 thereon, the compliant bumps 52 are rearranged on any area of the die 50 for electrically connecting to the die 50 and the substrate 54. A joint area of the bumps after rearrangement is smaller than a joint area of the bumps on the center, and an adhesive 53 daubed on a joint area of the substrate 54 and the die 50 for jointing the substrate 54 and the die 50. The rearrangement of the compliant bumps 52 makes a surrounding (or distribution) area smaller than an electrode of the original die 50. Therein, the adhesive 53 is comprised of an anisotropic conductive film, UV glue, or a non-conductive glue; the substrate is an organic substrate, a ceramic substrate, a glass substrate, a silicon substrate, or a GaAs substrate. The integrated circuit device further comprises a non-conductive adhesive 55 daubed on a non-conductive joint area of the substrate 54 and the die 50 so as to reduce the amount of conductive adhesive required, thereby reducing costs.

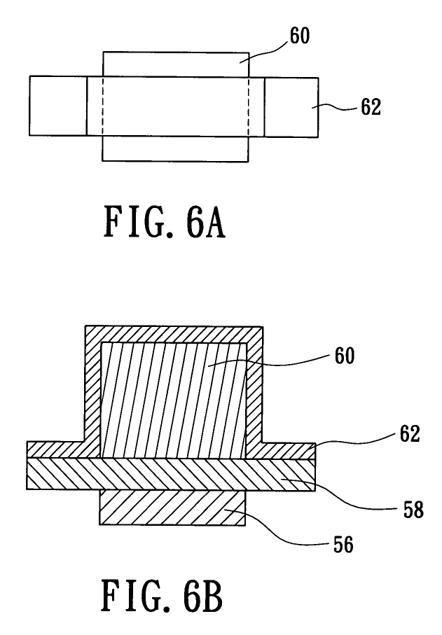

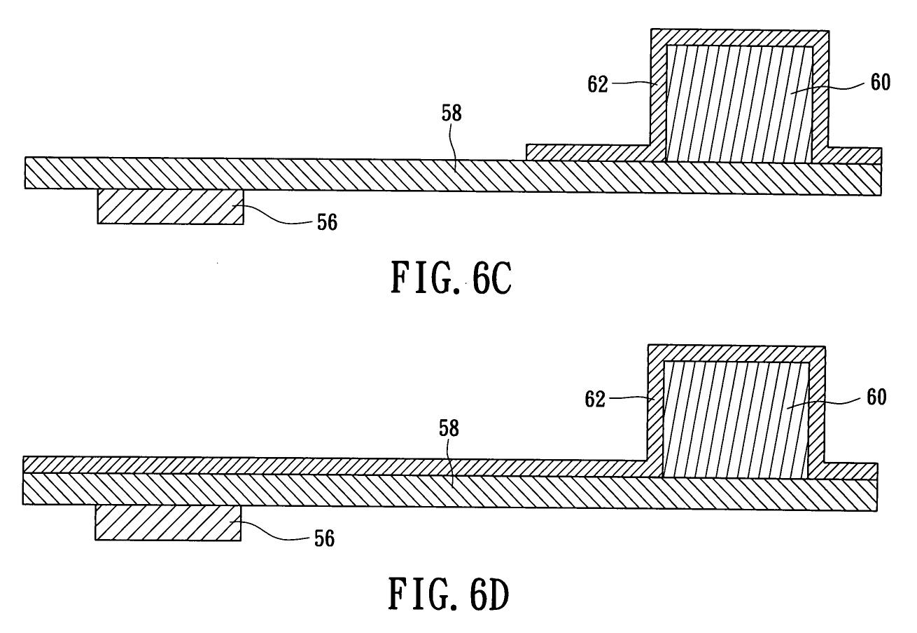

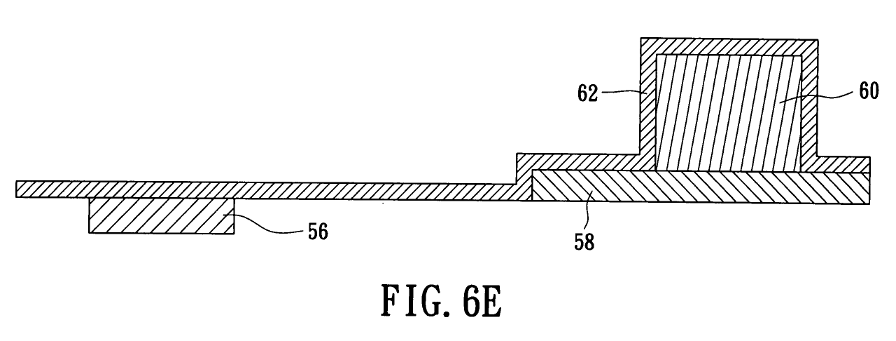

Reference is made to FIG. 6A which is a top view showing the structures of the compliant bumps of the present invention. A bump 60 of the compliant bumps 52 is not covered by a second metal layer 62. The other two opposite side surfaces that don cover the second metal layer 62 block the lateral electrical connection of the adjacent compliant bumps 52 so that the compliant bumps 52 centrally disposed on the center of the die 50 will not short. This is a first embodiment of the present invention. When it is implemented to the compliant bumps 52, the second metal layer 62 covers one side, two sides, three sides or all of the sides of the bump 60. Therein, the adhesive 53 is comprised of an anisotropic conductive film.

Reference is made to FIG. 6B which is a schematic view showing the structure of the compliant bumps of the present invention. The compliant bumps are formed with a first metal layer 58, the bump 60, and the second metal layer 62. The second metal layer 62 covers two opposite side surfaces of the bump 60 to connect with the first metal layer 58 for electrically connecting the substrate 54 and the electrodes 56 of the die 50. Therein, the first metal layer 58 is a Ti—W metal layer, the bump 60 is formed with a polymer, and the second metal layer 62 is an Au metal layer.

Reference is made to FIG. 6C which is an extended structure schematic view showing the first embodiment of the compliant bumps of the present invention. By extending the first metal layer 58 to change the position of the compliant bumps 52, the compliant bumps 52 are centrally disposed on the die 50 without changing the electrical characteristics and the wiring arrangement of the die 50. The manufacture of the bump 60 can also use the process of producing the compliant bumps, without changing the number of masks or the number of processes needed, as long as the first metal layer 58 is extended to move the compliant bumps 52 to the center of the die 50.

Reference is made to FIG. 6D which is an extended structure schematic view showing the second embodiment of the compliant bumps of the present invention. By extending the first metal layer 58 and the second metal layer 62 to change the position of the compliant bumps 52 simultaneous, the compliant bumps 52 are centrally disposed on the die 50 without changing the electrical characteristics and the wiring arrangement of the die 50. The manufacture of the bump 60 can also use the process of producing the compliant bumps, without changing the number of masks or the number of processes needed, as long as the first metal layer 58 and the second metal layer 62 are extended to move the compliant bumps 52 to the center of the die 50.

Reference is made to FIG. 6E which is an extended structure schematic view showing the second embodiment of the compliant bumps of the present invention. By extending the second metal layer 62 to change the position of the compliant bumps 52, the compliant bumps 52 are centrally disposed on the die 50 without changing the electrical characteristics and the wiring arrangement of the die 50. The manufacture of the bump 60 can also use the process of producing the compliant bumps, without changing the number of masks or the number of processes needed, as long as the second metal layer 62 is extended to move the compliant bumps 52 to the center of the die 50.

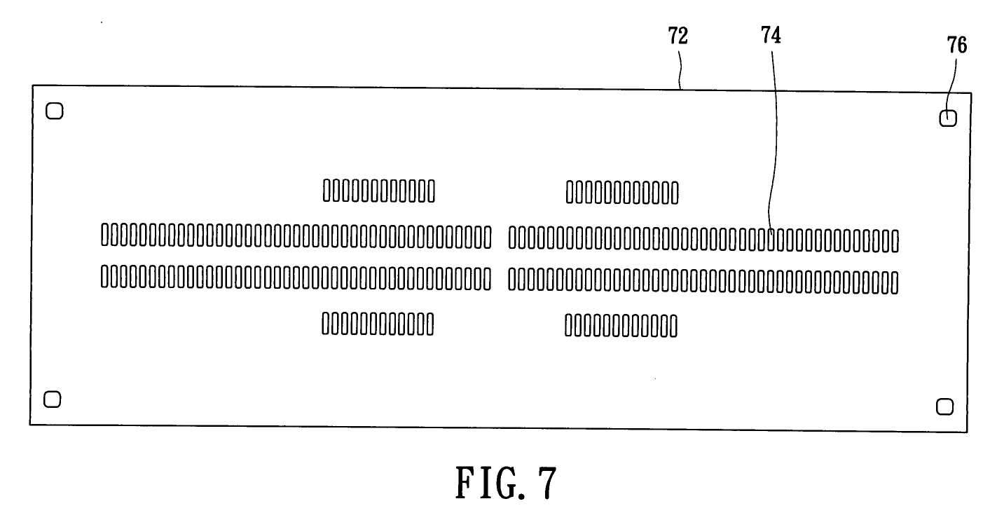

Reference is made to FIG. 7, which is a schematic view showing the second embodiment of the compliant bumps disposed on the die of the present invention. Included are a die 72 which has a surface and a plurality of compliant bumps 74 thereon, the compliant bumps 74 are centrally corresponded on the die 72, and a plurality of non-connecting electrically compliant bumps 76 are disposed in a corner of the die 72 or opposite to a side of the compliant bumps for maintaining the parallel of the joint.

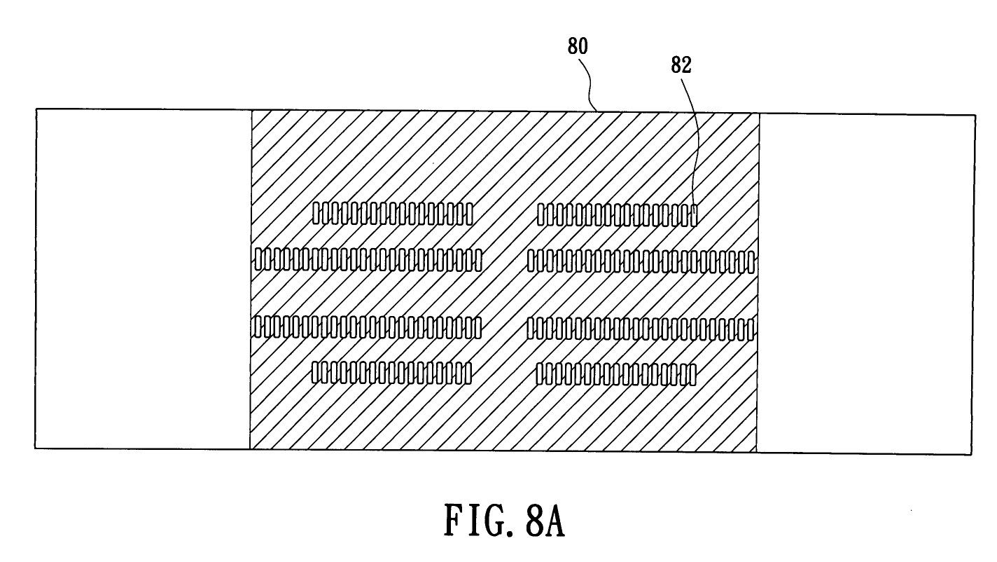

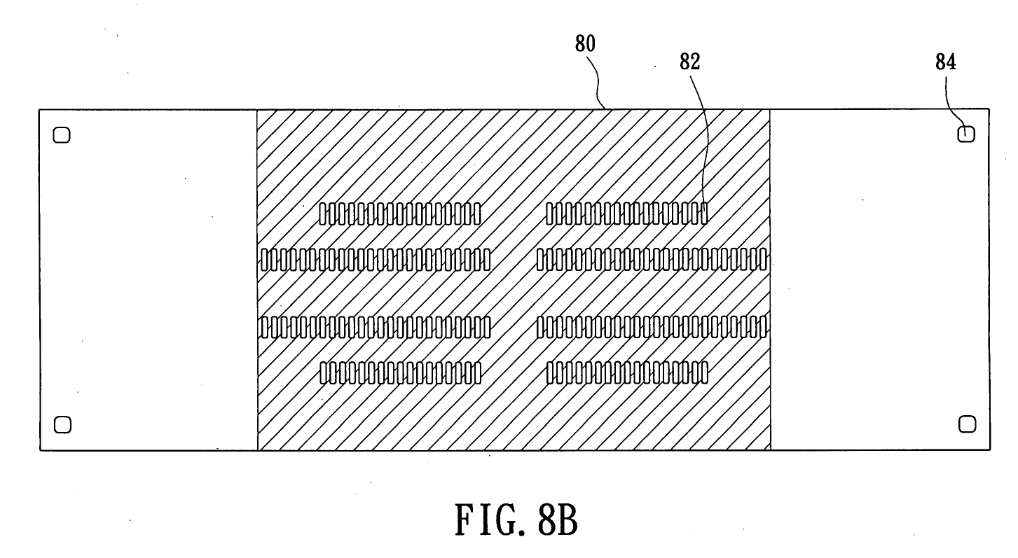

Reference is made to FIG. 8A, which is a schematic view showing the third embodiment of the compliant bumps disposed on the die of the present invention. Included are a die 80 and a plurality of compliant bumps 82 disposed on reduced distance from the second sides of the die 80. Therein, the reduced distance is smaller than the die 80 areas.

Reference is made to FIG. 8B, which is a schematic view showing the fourth embodiment of the compliant bumps disposed on the die of the present invention. Included are a die 80 and a plurality of compliant bumps 82 disposed on reduced distance from the second side of the die 80, and a plurality of non-connecting electrically compliant bumps 84 that are disposed in a corner of the die 80 or opposite to a side of the compliant bumps for maintaining the parallel of the joint. Therein, the reduced distance is smaller than the die 80 areas.

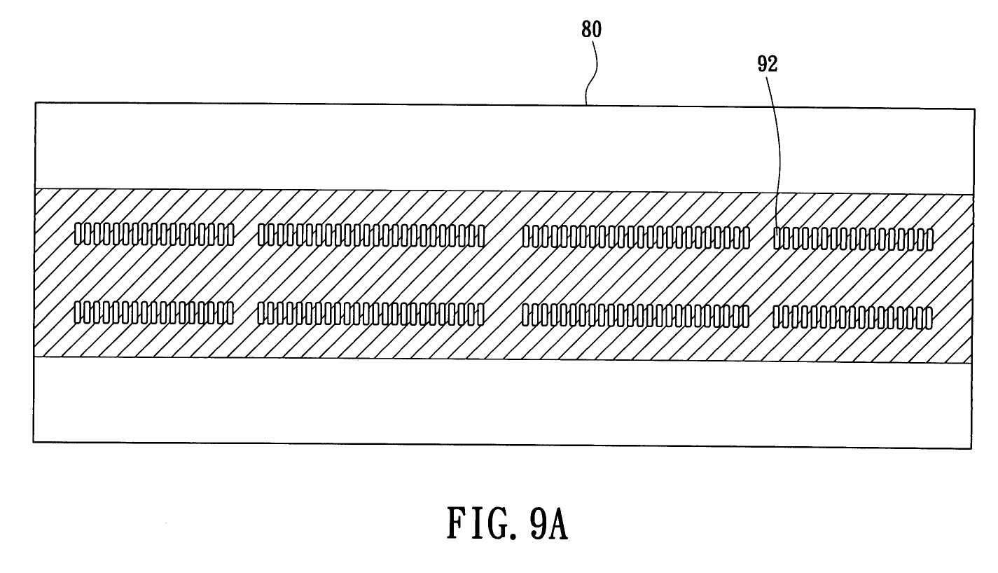

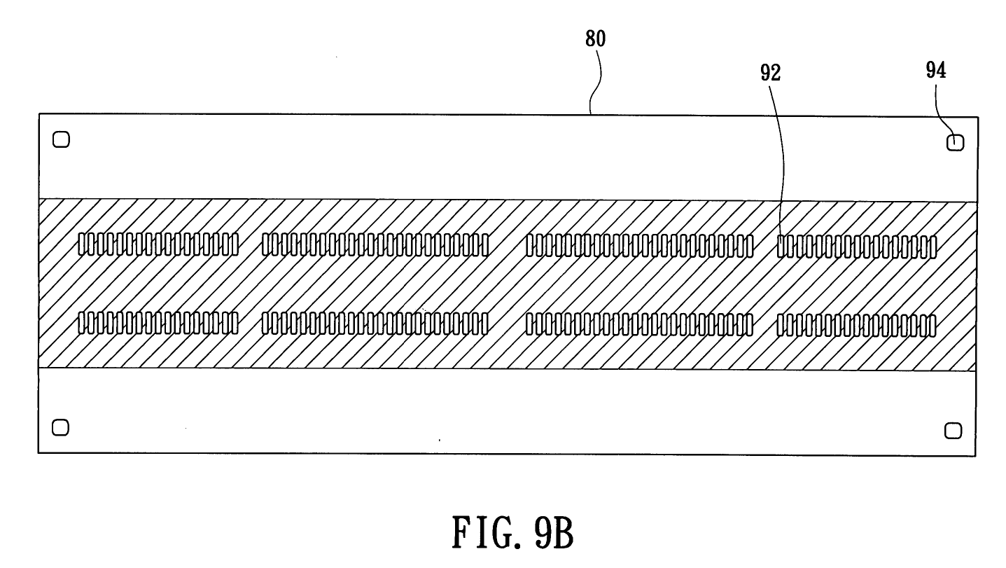

Reference is made to FIG. 9A, which is a schematic view showing the fifth embodiment of the compliant bumps disposed on the die of the present invention. Included are a die 80 and a plurality of compliant bumps 92 centrally disposed on reduced distance from the other sides of the die 80. Therein, the reduced distance is smaller than the die 80 areas.

Reference is made to FIG. 9B, which is a schematic view showing the sixth embodiment of the compliant bumps disposed on the die of the present invention. Included is a die 80 and a plurality of compliant bumps 92 centrally disposed on reduced distance from the other sides of the die 80, and a plurality of non-connecting electrically compliant bumps 94 disposed in a corner of the die 80 or opposite to a side of the compliant bumps for maintaining the parallel of the joint.

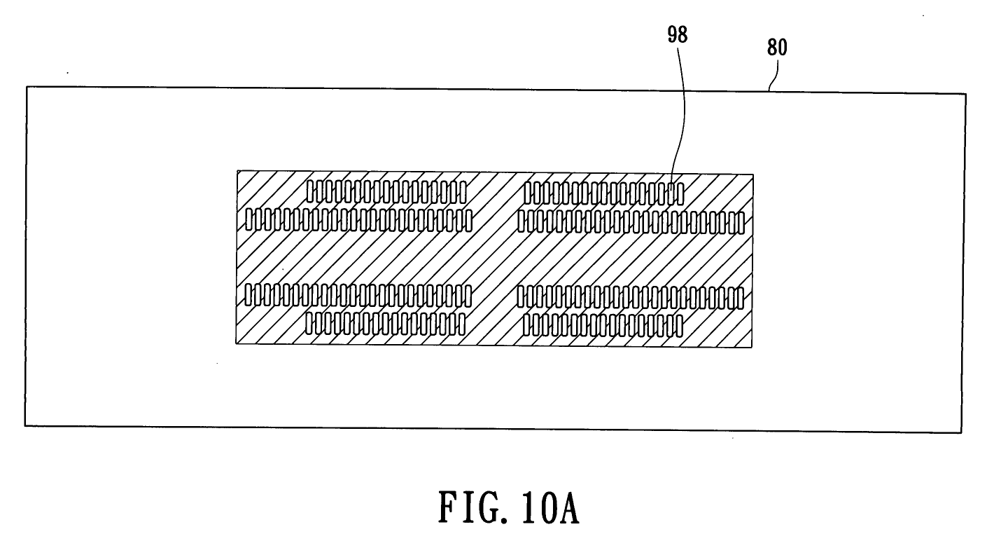

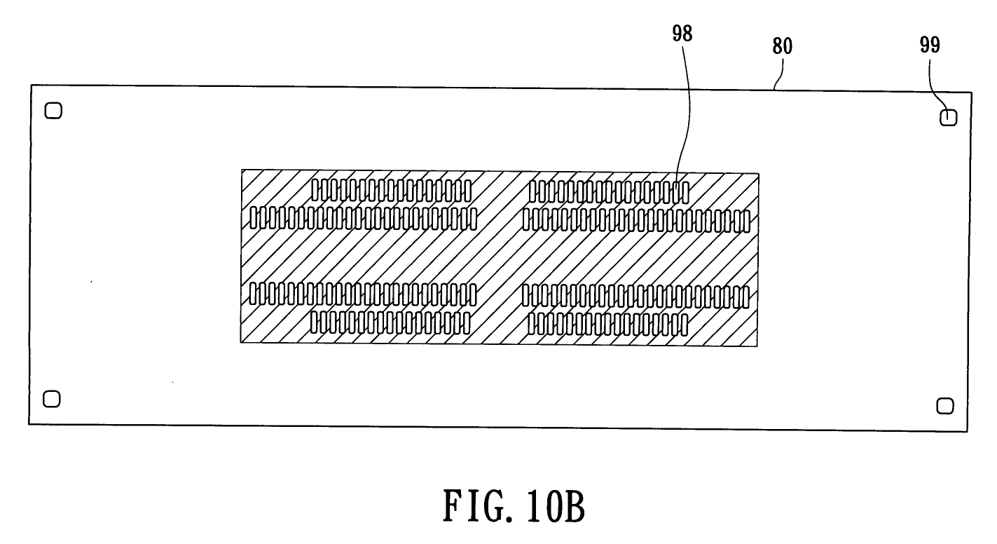

Reference is made to FIG. 10A, which is a schematic view showing the seventh embodiment of the compliant bumps disposed on the die of the present invention. Included is a die 80 and a plurality of compliant bumps 98 centrally disposed on reduced distance whose diagonal lines are half of the length of the die 80. Therein, the reduced distance is smaller than the die 80 areas.

Reference is made to FIG. 10B, which is a schematic view showing the eighth embodiment of the compliant bumps disposed on the die of the present invention. Included is a die 80 and a plurality of compliant bumps 98 centrally disposed on reduced distance whose diagonal lines are half of the length of the die 80, and a plurality of non-connecting electrically compliant bumps 99 that are disposed in a corner of the die 80 or opposite to a side of the compliant bumps for maintaining the parallel of the joint. Therein, the reduced distance is smaller than the die 80 areas.

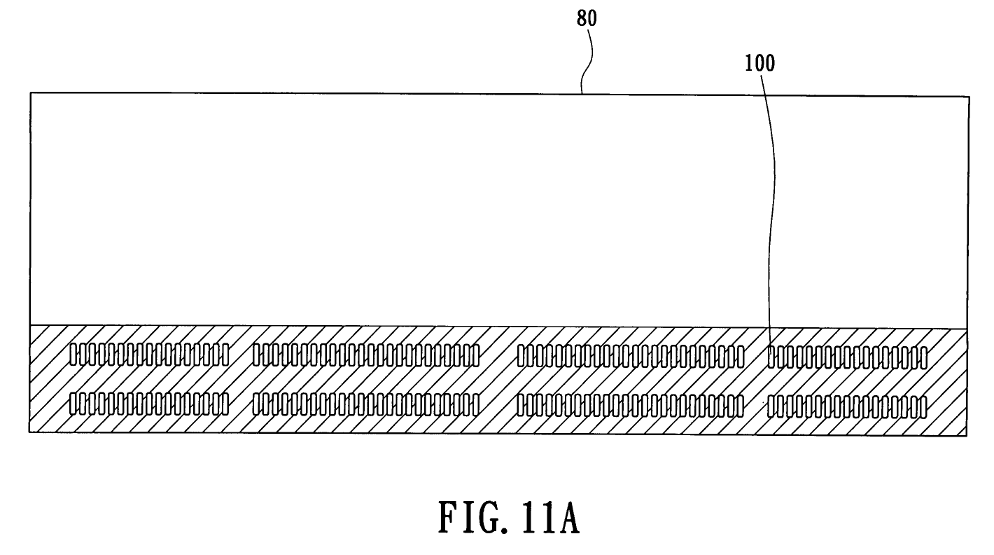

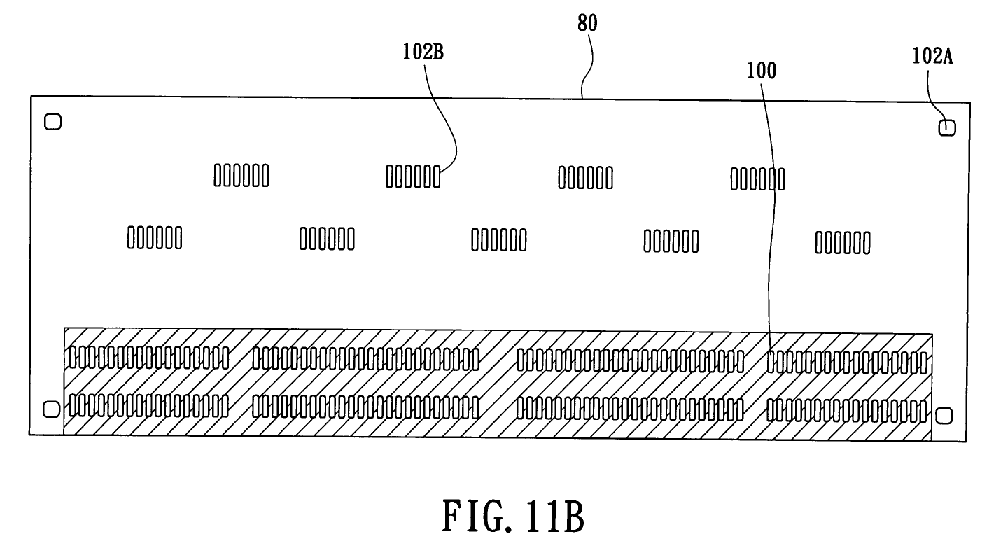

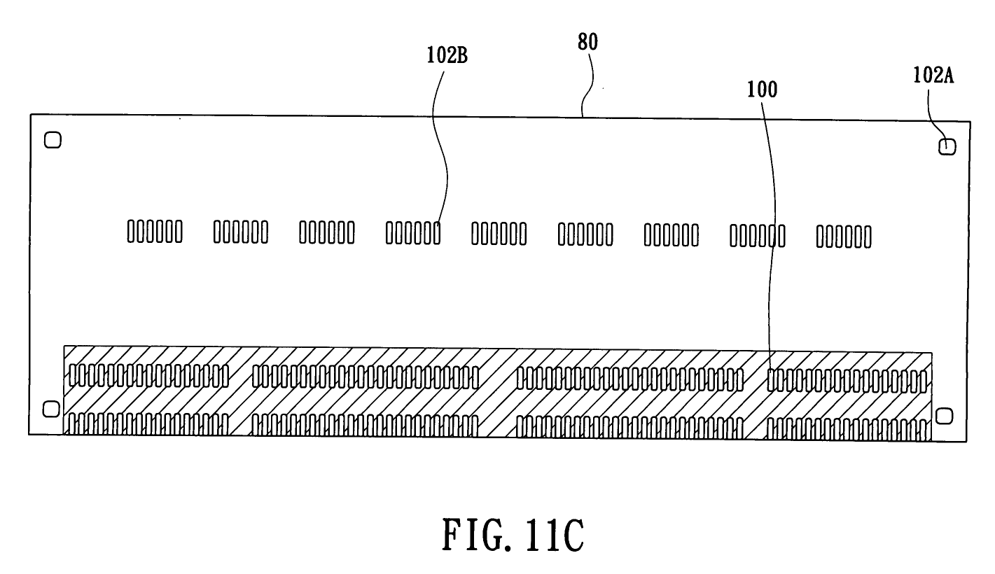

Reference is made to FIG. 11A, which is a schematic view showing the ninth embodiment of the compliant bumps disposed on the die of the present invention. Included is a die 80 and a plurality of compliant bumps 100 centrally disposed on one side of the die 80.

Reference is made to FIG. 11B, which is a schematic view showing the tenth embodiment of the compliant bumps disposed on the die of the present invention. Included is a die 80 and a plurality of compliant bumps 100 centrally disposed on one side of the die 80, and a plurality of non-connecting electrically compliant bumps 102 that are disposed in a corner of the die 80 or opposite to a side of the compliant bumps for maintaining the parallel of the joint.

Reference is made to FIG. 11C, which is a schematic view showing the eleventh embodiment of the compliant bumps disposed on the die of the present invention. Included is a die 80 and a plurality of compliant bumps 100 centrally disposed on an electrode outside of the die 80, and a plurality of non-connecting electrically compliant bumps 102A and 102B that are disposed in a corner of the die 80 or opposite to a side of the compliant bumps 102B for maintaining the parallel of the joint.

The characteristics and efficiencies of the present invention are described below:

1. The bumps inwardly disposed on the center of the die avoid the delamination of the adhesives because of thermal stress, thereby maintaining the quality of the inner joints.

2. The joints of the bumps inwardly assembled on the center of the die maintain the same resistance value of the joints.

3. The position of the bumps move inwardly to extend the distance between the joints thereby prolonging their user life.

4. A non-conductive adhesive is used on a non-conductive joint area to reduce costs added in the prior art due to the need for a conductive adhesive.

5. The present invention avoids the bending of the glass substrate due to adhesive bleeding of the prior art.

Although the present invention has been described with reference to the preferred embodiments thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. An integrated circuit, comprising:
a die; and
a concentration of compliant bumps positioned on the die, wherein the concentration has a size constraint and the concentration of compliant bumps is positioned in any location on the die such that the concentration of compliant bumps maintains the size constraint.

2. The integrated circuit as claimed in claim 1, further comprising:
a first metal layer connected to an electrode positioned on the die;
a second metal layer positioned on top of the first metal layer;
a positioned compliant bump core between a portion of the first metal layer and a portion of the second metal layer;
wherein the first metal layer for extending to change the compliant bump core position.

3. The integrated circuit as claimed in claim 2, wherein the first metal layer is a Ti—W metal layer.

4. The integrated circuit as claimed in claim 2, wherein the compliant bumps are formed with polymer.

5. The integrated circuit as claimed in claim 2, wherein the second metal layer is an Au metal layer.

6. The integrated circuit as claimed in claim 1, further comprising:
a first metal layer connected to an electrode positioned on the die;
a second metal layer positioned on top of the first metal layer;
a positioned compliant bump core between a portion of the first metal layer and a portion of the second metal layer;
wherein the second metal layer for extending to change the compliant bump core position.

7. The integrated circuit as claimed in claim 6, wherein the first metal layer is a Ti—W metal layer.

8. The integrated circuit as claimed in claim 6, wherein the compliant bumps are formed with polymer.

9. The integrated circuit as claimed in claim 6, wherein the second metal layer is an Au metal layer.

10. The integrated circuit as claimed in claim 1, further comprising:
a first metal layer connected to an electrode positioned on the die;
a second metal layer positioned on top of the first metal layer;
a positioned compliant bump core between a portion of the first metal layer and a portion of the second metal layer;
wherein the first metal layer and second metal layer for extending to change the compliant bump core position simultaneous.

11. The integrated circuit as claimed in claim 10, wherein the first metal layer is a Ti—W metal layer.

12. The integrated circuit as claimed in claim 10, wherein the compliant bumps are formed with polymer.

13. The integrated circuit as claimed in claim 10, wherein the second metal layer is an Au metal layer.
